(19) United States
(12) Patent Application Publication
(10) Pub. No.: US 2014/0092682 A1
(43) Pub. Date: Apr. 3, 2014

(54) METHOD FOR PROGRAMMING AND READING FLASH MEMORY BY STORING LAST PROGRAMMING PAGE NUMBER

(71) Applicant: QUANTA STORAGE INC., Taoyuan County (TW)

(72) Inventors: Ying-Kai Yu, Taoyuan County (TW); Jin-Shing Hsieh, Taoyuan County (TW); Yi-Long Hsiao, Taoyuan County (TW)

(21) Appl. No.: 13/923,389

(22) Filed: Jun. 21, 2013

(30) Foreign Application Priority Data
Sep. 28, 2012 (CN) 201210367723.6

(51) Int. Cl. G11C 16/10

(52) U.S. Cl. CPC G11C 16/10
USPC 365/185.03; 365/185.12

(57) ABSTRACT

The invention is to provide a method for programming and reading a flash memory, storing the last programming page in a block while programming the flash memory, judging the programming times in the cell of the block by means of the last programming page and the order and distribution of the page in the predefined page distribution list of the block while reading the flash memory, and selecting the predefined voltage based on the judged programming times to implement the reading process for raising reading performance.

### BACKGROUND OF THE INVENTION

1. Field of the Invention

The present invention relates to a flash memory, and more particularly, to a method of storing a last programming page number of a flash memory to determine the number of programming times for performing a reading process.

2. Description of the Prior Art

A non-volatile flash memory is capable of remaining its stored data without power supply. Moreover, besides faster speed of erasing data, programming data and reading data, the non-volatile flash memory has smaller size and higher storage density. Therefore, the non-volatile flash memory has become a main data storage device.

Flash memories are divided into single level cell (SLC) flash memories, multi level cell (MLC) flash memories, triple level cell (TLC) memory cells and quad level cell (QLC) flash memories according to the number of bits stored in a memory cell, where an SLC is capable of storing an 1-bit data, an MLC is capable of storing a 2-bit data, a TLC is capable of storing a 3-bit data, and a QLC is capable of storing a 4-bit data.

FIG. 1 shows a programming voltage distribution of a conventional MLC flash memory. Taking an MLC flash memory for example, it is partitioned into a plurality of blocks for data storage. Each block includes a plurality of rows of MLCs 10 to form 256 pages, and each page has a corresponding logical address for facilitating data access control. Each MLC 10 includes a lower page L and a higher page H, and each page includes a plurality of memory circuit units 11, where different digital signals can be identified according to different voltages loaded by the memory circuit unit 11. An SLC F is further disposed after the MLC 10. The SLC F includes two flag circuit units 20. The different voltages loaded by the flag circuit units 20 indicate a once-programming phase and a twice-programming phase respectively. Hence, the flag circuit units 20 serve as flags indicative of the number of programming times of the MLC 10.

While the MLC flash memory is being programmed, a successively increased voltage is applied to the memory circuit unit 11 of the MLC 10 to prevent the MLC 10 from being damaged by the excessive voltage. Before the programming is initiated, the voltage level of the memory circuit unit 11 of the MLC 10 remains at an erasing voltage, and the voltage level of the flag circuit unit 20 of the SLC F remains at a once-programming flag voltage 21. During the once-programming phase of the MLC flash memory, a predefined voltage is added to the lower page L of the MLC 10 such that the memory circuit unit 11 is configured to have one of an erasing voltage 14 and a once-programming voltage 13 with different loadings, and the flag circuit unit 20 still remains at the once-programming flag voltage 21. While the MLC flash memory is being read, a predefined flag threshold voltage V5 is utilized to determine the flag recorded by the flag circuit unit 20 at the once-programming flag voltage 21. As the MLC 10 is only programmed once, a predefined once-programming threshold voltage V1 is utilized to identify the voltage of the memory circuit unit 11 of the lower page L, thus reading the stored data by identifying the digital signal being either ‘1’ or ‘0’.

During twice-programming the MLC flash memory, a predefined voltage is added to the higher page H of the MLC 10 such that the memory circuit unit 11 of the higher page H is configured to have one of four twice-programming voltages 15, 16, 17 and 18 with different loadings, and the flag circuit unit 20 is changed to a twice-programming flag voltage 22. While the MLC flash memory is being read, a predefined flag threshold voltage V5 is utilized to determine the flag recorded by the flag circuit unit 20 at the twice-programming flag voltage 22. As the MLC 10 is already programmed twice, a plurality of predefined twice-programming threshold voltages V2, V3 and V4 are utilized to identify the voltage of the memory circuit unit 11 of the higher page H, thus reading the stored data by identifying the digital signal being ‘11’, ‘10’, ‘01’ or ‘00’.

However, the flag voltage which represents the number of programming times the MLC flash memory is often affected by the added voltage during the programming, leading to failure of correctly determining the number of programming times. As a result, incorrect threshold voltages are selected for reading the stored data, resulting in data reading failure. Therefore, U.S. Pat. No. 8,107,291 discloses a solution which uses pre-stored dummy data to complete twice-programming of all memory cells when reading blocks of a flash memory. In this way, there is no need to determine the programming flag voltage. That is to say, the predefined twice-programming threshold voltage is used to read the blocks directly, and the function of using the flag to indicate the number of programming times and the structure of the SLC F are deleted so as to achieve an increased storage capacity.

However, when a reading operation is performed upon the flash memory proposed by the aforementioned U.S. Pat. No. 8,107,291, it costs extra time for completing twice-programming of all of the memory cells and then reading and processing the dummy data. This not only decreases the efficiency of reading, but also affects the storage capacity since a large amount of dummy data needs to be stored in the flash memory. Thus, there are still problems need to be solved in the field of programming and reading a flash memory.

### SUMMARY OF THE INVENTION

One of the objectives of the present invention is to provide a method of programming and reading a flash memory, which can determine the number of programming times correctly through storing a last programming page number of a block and referring to the stored last programming page number and a predefined page allocation table.

Another objective of the present invention is to provide a method of programming and reading a flash memory, which can improve the reading efficiency by determining the number of programming times to select correct threshold voltage(s) directly.

Yet another objective of the present invention is to provide a method of programming and reading a flash memory, which can omit the function of using a flag to record the number of programming times and the structure of the SLC, so as to simplify the programming and reading process.

Yet another objective of the present invention is to provide a method of programming and reading a flash memory, which only stores less data (i.e., the last programming page number of each block) into a controller or a predetermined block, so as to improve the design flexibility.

According to the present invention, a method for programming and reading a flash memory includes: storing a last programming page number of a block of the flash memory while programming the flash memory; receiving a reading command to read data stored in the block; determining a number of programming times of a cell of the block according to the stored last programming page number and a page order and a page allocation of a predefined page allocation table; and selecting one or more predefined threshold voltages based on the determined number of programming times and performing a reading process upon the cell.

According to the present invention, while the flash memory is being programmed, a programming command is received to store data into a block, and then a cell of the block is programmed according to the page order and the page allocation of the predefined page allocation table, where there is no SLC programming process for recording a flag indicative of the number of programming times. The last programming page number may be stored in a controller or a specific block of the flash memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is programming voltage distribution of a conventional MLC flash memory.

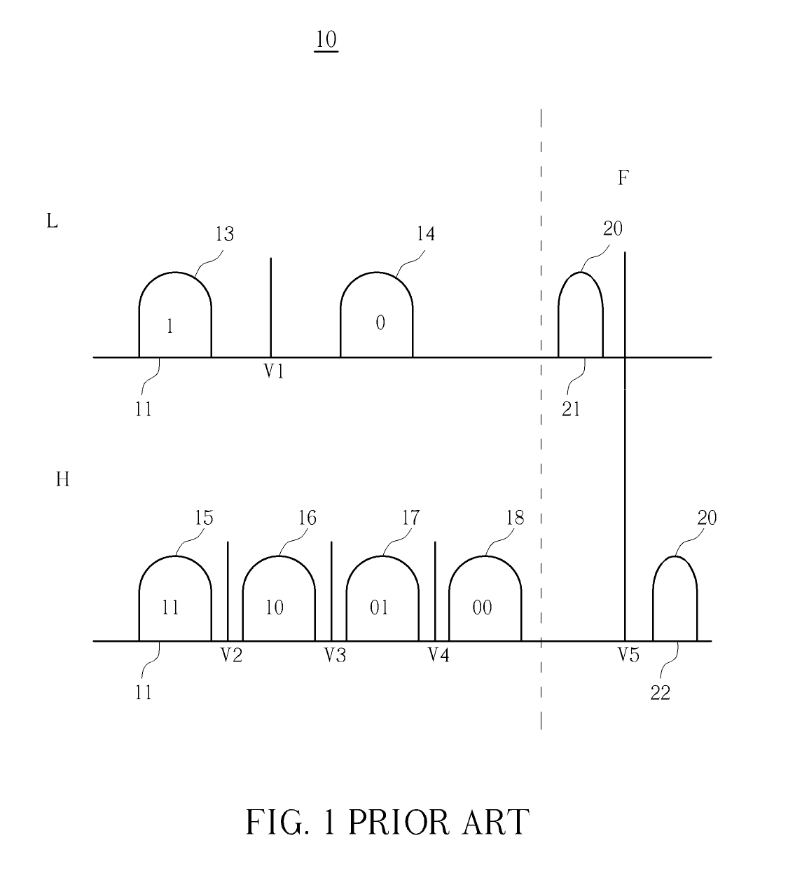

FIG. 2 is a diagram illustrating a structure of a flash memory according to an embodiment of the present invention.

FIG. 3 is a diagram illustrating a page allocation table according to an embodiment of the present invention.

FIG. 4 is a flowchart illustrating a method for programming a flash memory according to an embodiment of the present invention.

FIG. 5 is a flowchart illustrating a method for programming and reading a flash memory according to an embodiment of the present invention.

### DETAILED DESCRIPTION

To achieve the above objective, the technical means adopted by the present invention and the associated advantages/benefits will be described as follows with reference to preferred embodiments and figures.

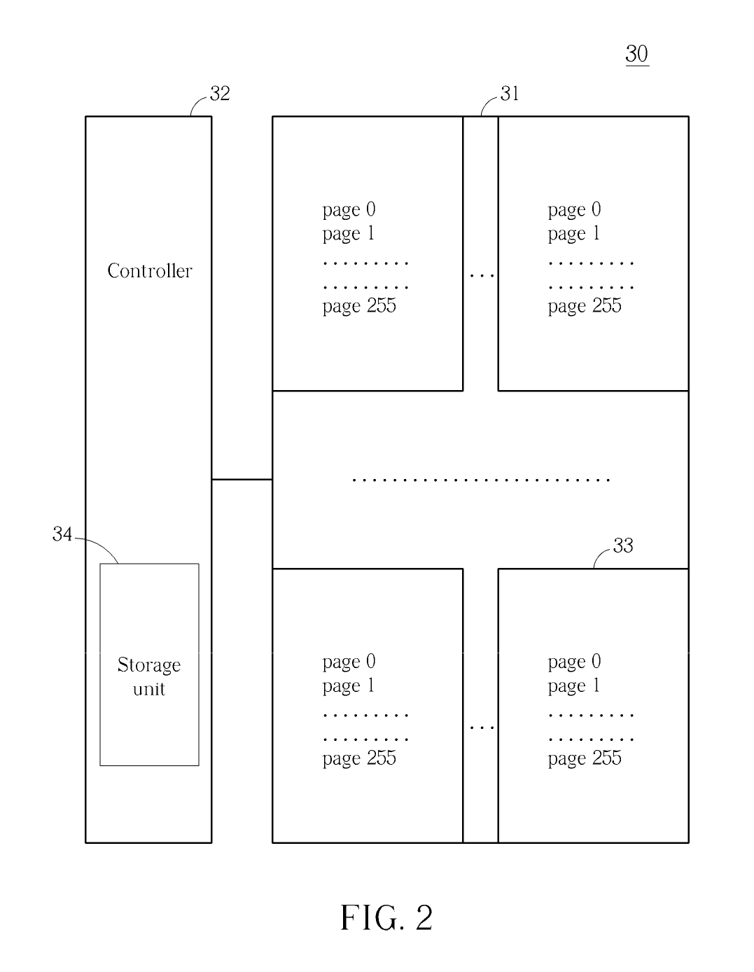

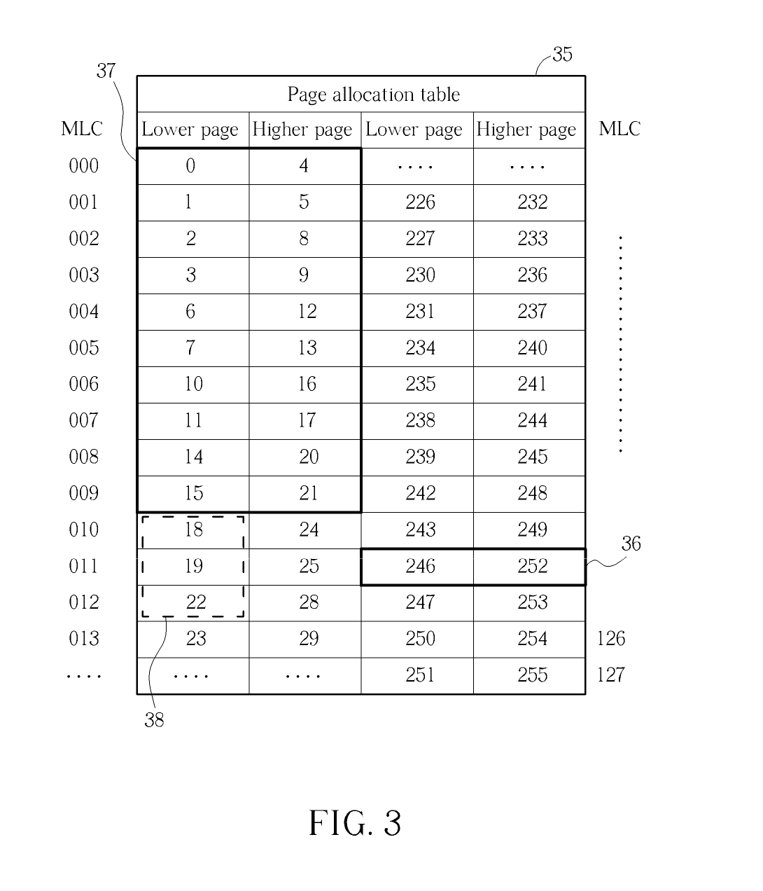

Please refer to FIG. 2 in conjunction with FIG. 3. FIG. 2 is a diagram illustrating a structure of a flash memory according to an embodiment of the present invention. FIG. 3 is a diagram illustrating a page allocation table according to an embodiment of the present invention. In FIG. 2, a flash memory 30 of the present invention includes at least a cell unit 31 and a controller 32, wherein the cell unit 31 includes a plurality of rows of cells partitioned into a plurality blocks 33. Each block 33 includes 256 pages. Each page includes a corresponding logical address, and is used for storing data. The controller 32 includes a storage unit 34 for storing control parameter(s) of the flash memory 30 and collaborating with the controller 32 to control access of the data stored in the cell unit 31.

When it needs to program the flash memory 30 for storing data, in order to prevent the programming voltage from affecting voltages of the neighboring pages, the flash memory 30 stores a predefined page allocation table 35 in the storage unit 34. The page allocation table 35 records cells of 256 cross-spaced pages in a block 33. Taking an MLC flash memory for example (which is not meant to be a limitation of the present invention), each MLC 36 in the page allocation table 35 of the block 33 of the MLC flash memory shown in FIG. 3 includes a lower page and a higher page, and is followed by no SLC for recording a flag indicative of the number of programming times. The 256 pages composed of the ‘000’^{th} MLC 36 to the ‘127’^{th} MLC 36 of the block 33 are numbered as page 0 to page 255. The page 0 to the page 3 are set at the ‘000’^{th} lower page to the ‘003’^{rd} lower page of the MLC 36, while the page 4 and the page 5 are set at the ‘000’^{th} higher page to the ‘001’^{st} higher page of the MLC 36. Then, the page 6 to the page 7 are set at the ‘004’^{th} lower page to the ‘005’^{th} lower page of the MLC 36, and the page 8 and the page 9 are set at the ‘002’^{th} higher page to the ‘003’^{th} higher page of the MLC 36. The page allocation table 35 is then completed by repeatedly setting the higher and lower pages of the MLC 36 in a two-page step and a cross-spaced manner until the page 254 and the page 255 are set at the ‘126’^{th} higher page to the ‘127’^{th} higher page of the MLC 36.

When the block 33 of the flash memory 30 is being programmed, although the voltage is increased according to the ascending order of page 0 to page 255 sequentially, the cross-spaced architecture avoids the increased voltage from being excessively concentrated on a certain part of the flash memory 30, which prevents the programming voltage from affecting the neighboring pages to thereby reducing the probability of data reading failure. Different types of flash memory 30 may have different cell levels and different integrated structures. Although the cross-spaced structures are not the same, each of the different cross-spaced structures has a specific order and allocation of pages to form the predefined page allocation table 35 used for controlling data access of the flash memory 30.

According to the method of programming and reading the flash memory as proposed by the present invention, while the flash memory 30 is programmed according to the predefined page allocation table 35, the last programming page number of each block 33 (e.g., the last programming page is page 22) is stored into the storage unit 34 or a predetermined block 33. While the flash memory 30 is being read, the last programming page number (i.e., page 22) is retrieved from the storage unit 34, and the page location is identified by referring to the page allocation table 35. For instance, as illustrated by a bold frame 37, the ‘000’^{th} MLC 36 to the ‘009’^{th} MLC 36 are already programmed twice; as illustrated by a dashed frame 38, the ‘010’^{th} MLC 36 to the ‘012’^{th} MLC 36 are only programmed once; and the rest of the MLCs 36 are not programmed yet. Therefore, the number of programming times can be correctly determined by only referring to the stored last programming page number and the page allocation table 35 without the need of a flag dedicated to recording the number of programming times.

Therefore, when a reading process is performed upon the block 33, the predefined twice-programming threshold voltages can be directly selected while reading stored data from page 0 to page 17 and page 20 to page 21 in the ‘000’^{th} MLC 36 to the ‘009’^{th} MLC 36 that are programmed twice; and the predefined once-programming threshold voltage can be directly selected while reading stored data from pages 18, 19 and 22 of the ‘010’^{th} MLC 36 to the ‘012’^{th} MLC 36 that are only programmed once. For the rest of the MLCs 36 which are determined as not being programmed yet, no read process will be executed, thereby saving the programming time, reading time and processing time of the dummy data and improving the reading efficiency.

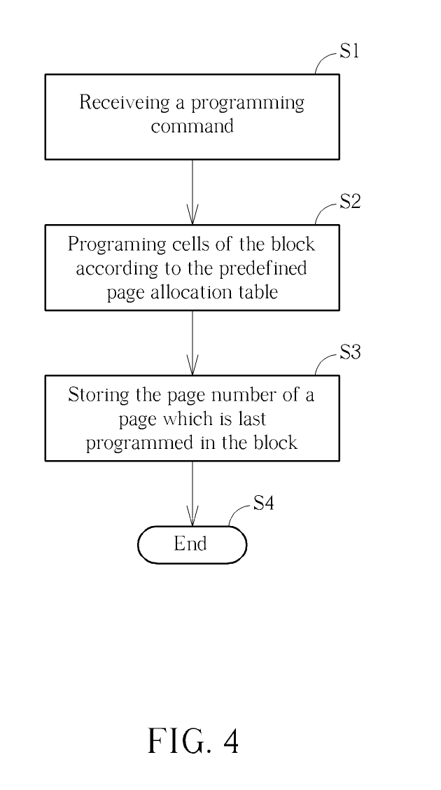

FIG. 4 is a flowchart illustrating a method for programming a flash memory according to an embodiment of the present invention. The detailed description of the disclosed method for programming a flash memory is as follows. In step S1, the flash memory receives a programming command to store data into a block; in step S2, the flash memory programs cells of the block according to the page order and the page allocation specified in the predefined page allocation table, where there is no SLC programming process of recording a flag indicative of the number of programming times; in step S3, the page number of a page which is last programmed in the block (i.e., the last programming page number of the block) is stored; and then the flow goes to step S5 to end the method of programming the flash memory.

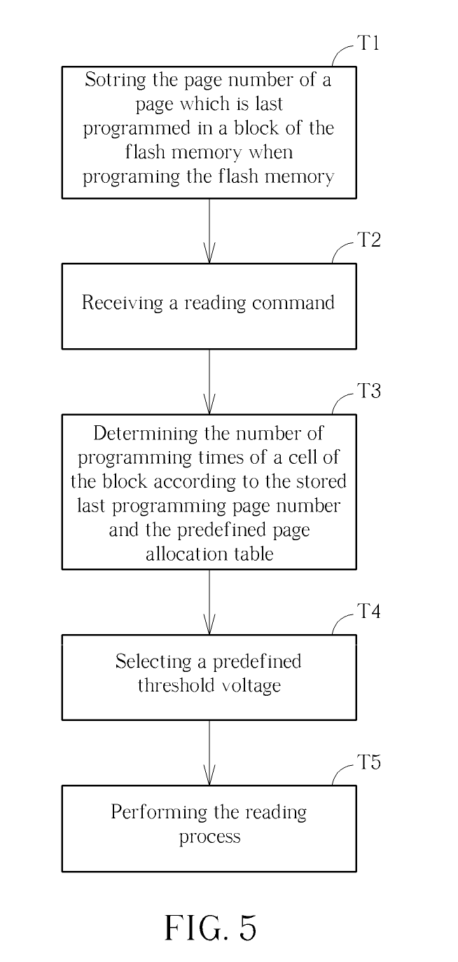

FIG. 5 is a flowchart illustrating a method for programming and reading a flash memory according to an embodiment of the present invention. The detailed description of the disclosed method for programming and reading a flash memory is as follows. In step T1, the flash memory is programmed, and the page number of a page which is last programmed in a block of the flash memory (i.e., the last programming page number of a block in the flash memory) is stored; in step T2, a reading command is received to read data stored in the block; in step T3, the number of programming times of a cell of the block is determined according to the stored last programming page number and a page order and a page allocation specified in the predefined page allocation table; in step T4, a predefined threshold voltage is selected based on the determined number of programming times; and in step T5, the reading process applied to the cell is performed.

In summary, the present invention can determine the number of programming times correctly through storing a last programming page number of a block while programming the block and then referring to the stored last programming page number and a predefined page allocation table, where no conventional flag indicative of the number of programming times is needed. The present invention further improves the reading efficiency by determining the number of programming times, selecting a correct threshold voltage directly, and reading the block rapidly. Moreover, the present invention omits the function of using a flag to record the number of programming times and the structure of the SLC, and thus does not need to program, read and process the conventional dummy data. In this way, the programming and reading process is simplified. Besides, due to the face that only the last programming page number of each block is stored, the present invention stores less data and can improve the design flexibility by selecting a controller or a predetermined block to store the last programming page number of each block.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for programming and reading a flash memory, comprising:
storing a last programming page number of a block of the flash memory while programming the flash memory;
receiving a reading command to read data stored in the block;
determining a number of programming times of a cell of the block according to the stored last programming page number and a page order and a page allocation of a predefined page allocation table; and
selecting one or more predefined threshold voltages based on the determined number of programming times, and performing a reading process upon the cell.

2. The method for programming and reading the flash memory of claim 1, wherein the last programming page number is stored in a controller of the flash memory.

3. The method for programming and reading the flash memory of claim 1, wherein the last programming page number is stored in a specific block of the flash memory.

4. The method for programming and reading the flash memory of claim 1, wherein while the flash memory is being programmed, a programming command for storing data into the block is received, and then the cell of the block is programmed according to the page order and the page allocation of the predefined page allocation table.

5. The method for programming and reading the flash memory of claim 2, wherein while the flash memory is being programmed, there is no single level cell (SLC) programming process for recording a flag indicative of the number of programming times.

6. The method for programming and reading the flash memory of claim 1, wherein the predefined page allocation table has a specific page order and a specific page allocation.
